(19) United States
(12) Patent Application Publication
(10) Pub. No.: US 2009/0217874 A1
(43) Pub. Date: Sep. 3, 2009

(54) FILM DEPOSITING APPARATUS

(75) Inventor: Tatsuya FUJINAMI, Odawara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/393,691

(22) Filed: Feb. 26, 2009

(30) Foreign Application Priority Data
Feb. 29, 2008 (JP) 2008-050315

(51) Int. Cl. C23C 16/00

(52) U.S. Cl. 118/723 I

(57) ABSTRACT

A film depositing apparatus comprises: a transport unit that transports an elongated substrate; a chamber; an evacuating unit that creates a specified degree of vacuum within the chamber; a rotatable drum that is provided within the chamber, around which the substrate transported by the transport unit is wrapped in a specified surface region; and a film depositing unit comprising a film depositing electrode spaced apart from and in a face-to-face relationship with the drum, a radio-frequency power source section for applying a radio-frequency voltage to the film depositing electrode, and a feed gas supply section from which a feed gas for forming a film is supplied into a space between the drum and the film depositing electrode, wherein a distribution of values of a distance between the film depositing electrode and the drum lies within 20% over an entire region of the film depositing electrode.

The entire contents of a document cited in this specification are incorporated herein by reference.

### BACKGROUND OF THE INVENTION

The present invention relates to a film depositing apparatus capable of film formation by CCP (capacitively coupled plasma) enhanced CVD on a surface of a substrate wrapped around a drum and, more particularly, to a film depositing apparatus that is capable of continuously forming films of satisfactory quality and which yet can be manufactured at low cost.

While various types of apparatus are known to be capable of continuous film deposition on an elongated substrate (a web of substrate) in a vacuum-filled chamber by plasma-enhanced CVD, an exemplary system uses a drum electrically connected to the ground and an electrode positioned in a face-to-face relationship with the drum and connected to a radio-frequency power source.

In this type of film depositing apparatus, the substrate is wrapped around a specified area of the drum, which is then rotated to thereby transport the substrate in a longitudinal direction as it is in registry with a specified film depositing position, with a radio-frequency voltage being applied between the drum and the electrode to form an electric field while, at the same time, a feed gas for film deposition as well as argon gas and the like are introduced between the drum and the electrode, whereby a film is deposited on the surface of the substrate by plasma-enhanced CVD. This type of film depositing apparatus has already been proposed (see JP 2006-152416 A).

JP 2006-152416 A discloses an apparatus for plasma-enhanced CVD that comprises a reaction compartment, gas inlets through which reactive gases are introduced into the reaction compartment, an anode and a cathode electrode that are provided within the reaction compartment to generate plasma discharge between themselves, and a transport mechanism that transports a flexible substrate between the anode and the cathode electrode; the apparatus treats the flexible substrate by plasma-enhanced CVD.

The anode electrode has a curved, first discharge surface whereas the cathode electrode has a second discharge surface that is curved along the first discharge surface. The cathode electrode is provided with an electrode-to-electrode distance adjusting mechanism for moving it in a direction parallel to the diameter of the anode electrode, as well as a curvature adjusting mechanism for performing fine adjustment on the curvature of the second discharge surface in accordance with the distance between the anode and cathode electrodes.

Note that the electrode-to-electrode distance adjusting mechanism is capable of translating the center of gravity of the cathode electrode by small amounts with millimeter-scale precision whereas the curvature adjusting mechanism is composed of a piezoelectric device.

### SUMMARY OF THE INVENTION

A problem with the plasma-enhanced CVD apparatus disclosed in JP 2006-152416 A is that it has such a complex structure that it takes considerable cost to manufacture. Another problem is that if the cathode electrode is fabricated as a monolithic structure, high production cost is required to attain the desired precision in molding and that once this electrode is molded, no adjustment is possible by means of re-processing.

A further problem with the plasma-enhanced CVD apparatus of JP 2006-152416 A is that it takes no account of the possibility that the cathode or the anode electrode might be deformed if a temperature elevation occurs due to plasma during film deposition. Because of this, the plasma-enhanced CVD apparatus of JP 2006-152416 A might potentially fail to yield films of satisfactory quality.

An object, therefore, of the present invention is to solve the aforementioned problems of the prior art by providing a film depositing apparatus that is capable of continuously forming films of good quality and which yet can be manufactured at low cost.

A film depositing apparatus according to the invention comprises: a transport means that transports an elongated substrate in a specified transport path; a chamber; an evacuating unit that creates a specified degree of vacuum within the chamber; a rotatable drum that is provided within the chamber, that has an axis of rotation in a direction perpendicular to a direction in which the substrate is transported, and around which the substrate transported by the transport means is wrapped in a specified surface region; and a film depositing unit comprising a film depositing electrode spaced apart from and in a face-to-face relationship with the drum, a radio-frequency power source section for applying a radio-frequency voltage to the film depositing electrode, and a feed gas supply section from which a feed gas for forming a film is supplied into a space between the drum and the film depositing electrode, wherein a distribution of values of a distance between the film depositing electrode and the drum lies within 20% over an entire region of the film depositing electrode.

### BRIEF DESCRIPTION OF THE DRAWINGS

FIG. 1 is a schematic diagram showing a film depositing apparatus according to an embodiment of the present invention.

FIG. 2 is a schematic perspective view showing the film depositing electrode in the film depositing apparatus according to the embodiment of the present invention.

FIG. 3 is a schematic diagram showing the relative positions of the drum and the film depositing electrode in the film depositing apparatus according to the embodiment of the present invention.

FIG. 4 is a schematic diagram showing the film depositing apparatus used in Examples of the present invention.

### DETAILED DESCRIPTION OF THE INVENTION

On the following pages, the film depositing apparatus of the present invention is described in detail with reference to the preferred embodiment shown in the accompanying drawings.

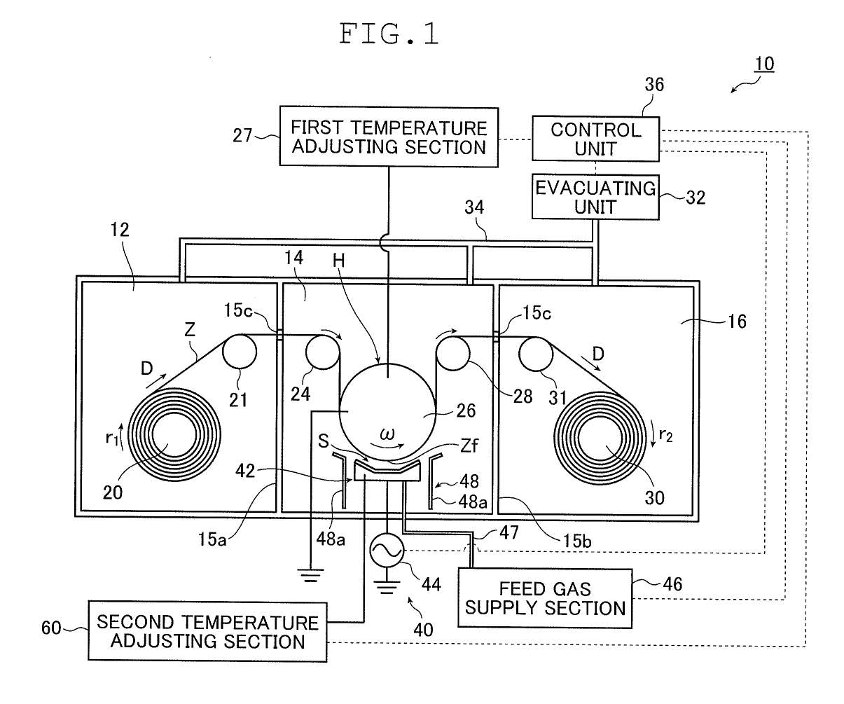

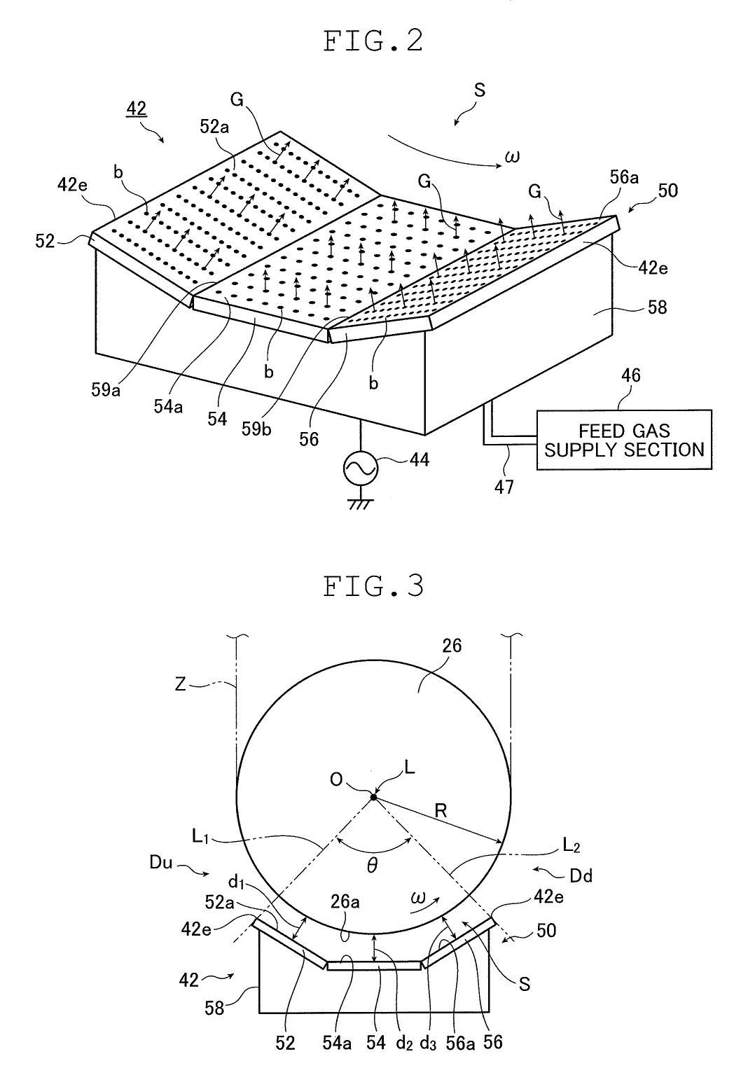

FIG. 1 is a schematic diagram showing a film depositing apparatus according to the preferred embodiment of the present invention. FIG. 2 is a schematic perspective view showing the film depositing electrode in the film depositing apparatus shown in FIG. 1. FIG. 3 is a schematic diagram showing the relative positions of the drum and the film depositing electrode in the film depositing apparatus shown in FIG. 1.

The film depositing apparatus generally indicated by 10 in FIG. 1 is a roll-to-roll type machine that forms a film with a specified function on the surface Zf of a substrate Z or on the surface of an organic layer if it is formed on the surface Zf of the substrate Z; the film depositing apparatus 10 is typically employed to produce functional films such as an optical film or a gas barrier film.

The film depositing apparatus 10 is an apparatus for depositing a film on an elongated substrate Z (a web of substrate Z) by capacitively coupled plasma enhanced CVD; it comprises basically a feed compartment 12 for feeding the elongated substrate Z, a film depositing compartment (chamber) 14 for forming a film on the elongated substrate Z, a take-up compartment 16 for winding up the elongated substrate Z after the film has been formed on it, an evacuating unit 32, and a control unit 36. The control unit 36 controls the actions of the individual elements of the film depositing apparatus 10.

In the film depositing apparatus 10, the feed compartment 12 and the film depositing compartment 14 are partitioned by a wall 15a whereas the film depositing compartment 14 and the take-up compartment 16 are partitioned by a wall 15b; a slit of opening 15c through which the substrate Z can pass is formed in each of the walls 15a and 15b.

In the film depositing apparatus 10, each of the feed compartment 12, the film depositing compartment 14 and the take-up compartment 16 is connected to the evacuating unit 32 via a piping system 34. The evacuating unit 32 creates a specified degree of vacuum in the interiors of the feed compartment 12, the film depositing compartment 14, and the take-up compartment 16.

To evacuate the feed compartment 12, the film depositing compartment 14 and the take-up compartment 16 to maintain a specified degree of vacuum, the evacuating unit 32 has vacuum pumps such as a dry pump and a turbo-molecular pump. Each of the feed compartment 12, the film depositing compartment 14 and the take-up compartment 16 is equipped with a pressure sensor (not shown) for measuring the internal pressure.

Note that the ultimate degree of vacuum that should be created in the feed compartment 12, the film depositing compartment 14 and the take-up compartment 16 by the evacuating unit 32 is not particularly limited and an adequate degree of vacuum suffices to be maintained in accordance with such factors as the method of film deposition to be performed. The evacuating unit 32 is controlled by the control unit 36.

The feed compartment 12 is a site for feeding the elongated substrate Z, where a substrate roll 20 and a guide roller 21 are provided.

The substrate roll 20 is for delivering the elongated substrate Z continuously and it typically has the substrate Z wound around it.

The substrate roll 20 is typically connected to a motor (not shown) as a drive source. By means of this motor, the substrate roll 20 is rotated in a direction r₁ in which the substrate Z is rewound; in the embodiment under consideration, the substrate roll 20 is rotated clockwise to deliver the substrate Z continuously in FIG. 1.

The guide roller 21 is for guiding the substrate Z into the film depositing compartment 14 in a specified transport path. The guide roller 21 is composed of a known guide roller.

In the film depositing apparatus 10 of the embodiment under consideration, the guide roller 21 may be a drive roller or a follower roller. Alternatively, the guide roller 21 may be a roller that works as a tension roller that adjusts the tension that develops during the transport of the substrate Z.

In the film depositing apparatus of the present invention, the substrate Z is not particularly limited and all kinds of substrates can be employed as long as films can be formed by vapor-phase deposition techniques. Usable as the substrate Z are various resin films such as a PET film, and various metal sheets such as an aluminum sheet.

The take-up compartment 16 is a site where the substrate Z with a film that has been formed on the surface Zr in the film depositing compartment 14 is wound up; in this take-up compartment 16, there are provided a take-up roll 30 and a guide roller 31.

The take-up roll 30 is a device by which the substrate z on which a film has been deposited is wound up in a roll.

The take-up roll 30 is typically connected to a motor (not shown) as a drive source. By means of this motor, the take-up roll 30 is rotated to wind up the substrate Z after the film deposition step.

By means of the motor, the take-up roll 30 is rotated in a direction r₂ in which the substrate Z is wound up; in the embodiment under consideration, the take-up roll 30 is rotated clockwise in FIG. 1, whereupon the substrate Z after the film deposition step is wound up continuously.

The guide roller 31 is similar to the aforementioned guide roller 21 in that the substrate Z being delivered from the film depositing compartment 14 is guided by this roller to the take-up roll 30 in a specified transport path. The guide roller 31 is composed of a known guide roller. Note that like the guide roller 21 in the feed compartment 12, the guide roller 31 may be a drive roller or a follower roller. Alternatively, the guide roller 31 may be a roller that works as a tension roller.

The film depositing compartment 14 functions as a vacuum chamber and it is a site where a film is continuously formed on the surface Zf of the substrate Z by a vapor-phase deposition technique, typically by plasma-enhanced CVD, as the substrate Z is being transported.

The film depositing compartment 14 is typically constructed by using materials such as stainless steel that are commonly employed in a variety of vacuum chambers.

In the film depositing compartment 14, there are provided two guide rollers 24 and 28, as well as a drum 26 and a film depositing unit 40.

The guide rollers 24 and 28 are spaced apart parallel to each other in a face-to-face relationship; they are also provided in such a way that their longitudinal axes cross at right angles to a direction D in which the substrate Z is transported.

The guide roller 24 is a device by which the substrate Z delivered from the guide roller 21 provided in the feed compartment 12 is transported to the drum 26. The guide roller 24 is rotatable, typically having an axis of rotation in a direction perpendicular to the direction D of transport of the substrate Z (the direction is hereinafter referred to as the axial direction), and its length in the axial direction is greater than the length in a width direction W perpendicular to the longitudinal direction of the substrate Z (the latter length is hereinafter referred to as the width of the substrate Z).

Note that the substrate roll 20 and the guide rollers 21 and 24 combine to constitute a first transport means according to the present invention.

The guide roller 28 is a device by which the substrate Z wrapped around the drum 26 is transported to the guide roller 31 provided in the take-up compartment 16. The guide roller 28 is rotatable, typically having an axis of rotation in the axial direction, and its length in the axial direction is greater than the width of the substrate Z.

Note that the guide rollers 28 and 31 as well as the take-up roll 30 combine to constitute a second transport means according to the present invention.

Except for the features just described above, the guide rollers 24 and 28 have the same structure as the guide roller 21 provided in the feed compartment 12, so they will not be described in detail.

The drum 26 is provided below the space H between the guide rollers 24 and 28. The drum 26 is so positioned that its longitudinal axis is parallel to those of the guide rollers 24 and 28. Also note that the drum 26 is electrically connected to the ground.

The drum 26 typically assumes a cylindrical shape and has an axis of rotation L (see FIG. 3) about which it is capable of rotating in the direction of rotation ω. Also note that the length in the axial direction of the drum 26 is greater than the width of the substrate Z. The drum 26, as it rotates with the substrate Z wrapped around its surface 26a (peripheral surface), transports the substrate Z in the transport direction D while it is kept in registry with a specified film depositing position.

It is assumed that the side to the direction of travel parallel to the direction of rotation ω of the drum 26, namely, the side to which the substrate Z is transported is the downstream side Dd, and the side opposite to this downstream side Dd is the upstream side Du.

For temperature adjustment, the drum 26 is provided in its center with a heater (not shown) for heating the drum 26 and a temperature sensor (also now shown) for measuring the temperature of the drum 26. The heater and the temperature sensor are connected to a first temperature adjusting section 27. The first temperature adjusting section 27 is connected to the control unit 36, which controls the first temperature adjusting unit 27 to adjust the temperature of the drum 26 such that it is held at a specified temperature. The heater (not shown), the temperature sensor (also not shown) and the first temperature adjusting section 27 combine to constitute a drum temperature adjusting mechanism.

As shown in FIG. 1, the film depositing unit 40 is provided below the drum 26, and the drum 26, with the substrate Z being wrapped around it, rotates so that a film is formed on the surface Zf of the substrate Z as it is transported in the transport direction D.

The film depositing unit 40 is a device to form a film by capacitively coupled plasma enhanced CVD (CCP-CVD). The film depositing unit 40 has a film depositing electrode 42, a radio-frequency power source 44, a feed gas supply section 46, a partition section 48, and a second temperature adjusting section 60. The control unit 36 controls the radio-frequency power source 44, the feed gas supply section 46 and the second temperature adjusting section 60 in the film depositing unit 40.

In the film depositing unit 40, the film depositing electrode 42 is provided in the lower part of the film depositing compartment 14, with a specified clearance S being provided relative to the surface 26a of the drum 26.

As shown in FIG. 2, the film depositing electrode 42 has a film depositing electrode assembly 50 and a holder 58 that holds the film depositing electrode assembly 50.

The film depositing electrode assembly 50 typically has three film depositing electrode plates 52, 54 and 56 that are each in a rectangular form.

As shown in FIG. 3, the film depositing electrode plates 52, 54 and 56 are arranged in the direction of rotation ω so as to follow the surface 26a of the drum 26, with their lengths being parallel to the axis of rotation L of the drum 26 and with their surfaces 52a, 54a and 56a being oriented to the surface 26a of the drum 26. Typically, the respective film depositing electrode plates 52, 54 and 56 are positioned in such a way that they agree with lines tangent to circles that are concentric with the surface 26a of the drum 26.

In the embodiment under consideration, the distance between the surface 52a of the film depositing electrode plate 52 and the surface 26a of the drum 26 as measured on a line that is perpendicular to the surface 52a and which passes through the center of rotation O of the drum 26 is represented by d₁; the distance between the surface 54a of the film depositing electrode plate 54 and the surface 26a of the drum 26 as measured on a line that is perpendicular to the surface 54a and which passes through the center of rotation O of the drum 26 is represented by d₂; and the distance between the surface 56a of the film depositing electrode plate 56 and the surface 26a of the drum 26 as measured on a line that is perpendicular to the surface 56a and which passes through the center of rotation O of the drum 26 is represented by d₃. Each of these distances d₁ to d₃ is measured in the clearance S between the film depositing electrode 42 and the surface 26a of the drum 26.

Also note that the film depositing electrode plates 52, 54 and 56 contact to each other on the side closer to the drum 26 to establish electrical conduction. It suffices that the film depositing electrode plates 52, 54 and 56 have electrical conduction to each other and as long as electrical conduction is maintained between the respective film depositing electrode plates 52, 54 and 56 by a known method for establishing electrical conduction, they need not contact each other on the side closer to the drum 26.

The film depositing electrode assembly 50 in the film depositing electrode 42 is adapted to consist of the three film depositing electrode plates 52, 54 and 56 but this is not the sole case of the present invention. Less than three or more than three film depositing electrode plates may be provided as long as the distribution of the values of the distance (d₁, d₂, or d₃) in the clearance S between the surface of each film depositing electrode plate and the surface 26a of the drum 26 lies within 20% over the entire region of the film depositing electrode 42 (over the surfaces 52a, 54a and 56a of the film depositing electrode plates 52, 54, and 56).

Each of the film depositing electrode plates 52, 54 and 56 is equipped with a moving mechanism section (not shown) that is capable of changing the inclination of each electrode plate in the two directions that are parallel to its longer and shorter sides and which is also capable of adjusting the position of the film depositing electrode assembly 50 such that it is brought either toward or away from the surface 26a of the drum 26. By using this moving mechanism section to change either the inclination of each of the film depositing electrode plates 52, 54 and 56 or the position of the film depositing electrode assembly 50 or both, the film depositing electrode plates 52, 54 and 56 can be adjusted independently of each other so as to change the distance d₁, d₂ or d₃ between the surface 52a, 54a or 56a and the surface 26a of the drum 26.

Each of the film depositing electrode plates 52, 54 and 56 in the film depositing electrode 42 is connected to the radio-frequency power source 44, which applies a radio-frequency voltage to each of the film depositing electrode plates 52, 54 and 56 in the film depositing electrode 42. The radio-frequency power source 44 is capable of varying the radio-frequency power (RF power) to be applied.

Note that the film depositing electrode 42 and the radio-frequency power source 44 may optionally be connected to each other via a matching box in order to attain impedance matching.

The film depositing electrode 42 is of a type that is generally called “a shower head electrode” and the film depositing electrode plates 52, 54 and 56 each have a plurality of through-holes b formed at equal spacings in their surfaces 52a, 54a and 56a.

The holder 58 is for holding the film depositing electrode plates 52, 54 and 56 and with its interior being hollow and connected to the feed gas supply section 46 via a pipe 47. The hollow portion of the holder 58 communicates with the plurality of through-holes b formed in each of the surfaces 52a, 54a and 56a of the film depositing electrode plates 52, 54 and 56.

As will be described later, a feed gas G supplied from the feed gas supply section 46 flows through the pipe 47, the hollow portion of the holder 58 and the plurality of through-holes b in each of the film depositing electrode plates 52, 54 and 56 to be released from the respective surfaces 52a, 54a and 56a of the film depositing electrode plates 52, 54 and 56 so that it is supplied into the clearance S.

To adjust the temperatures of the individual film depositing electrode plates 52, 54 and 56, the holder 58 is equipped with a heater (not shown) for heating the individual film depositing electrode plates 52, 54 and 56 and temperature sensors (also not shown) for measuring the respective temperatures of the individual film depositing electrode plates 52, 54 and 56. The heater and the respective temperature sensors are connected to the second temperature adjusting section 60. The second temperature adjusting section 60 is connected to the control unit 36 which controls it to adjust the temperatures of the individual film depositing electrode plates 52, 54 and 56 such that they are held at specified temperatures. The heater (not shown), the temperature sensors (also not shown) and the second temperature adjusting section 60 combine to constitute an electrode temperature adjusting mechanism.

The first temperature adjusting section 27 and the second temperature adjusting section 60 ensure that the drum 26 has the same temperature as each of the film depositing electrode plates 52, 54 and 56.

The feed gas supply section 46 supplies the film-forming feed gas into the clearance S through the plurality of through-holes b formed in each of the surfaces 52a, 54a and 56a of the film depositing electrode plates 52, 54 and 56. The clearance S between the surface 26a of the drum 26 and the film depositing electrode 42 serves as a space where plasma is to be generated.

In the embodiment under consideration, if a SiO₂ film is to be formed, the feed gas G is a TEOS gas, with oxygen gas being used as an active species gas. If a silicon nitride film is to be formed, SiH₄, NH₃ and N₂ gases are used.

The feed gas supply section 46 may be chosen from a variety of gas introducing means that are employed in the CCP-CVD apparatus.

Also note that the feed gas supply section 46 may supply into the clearance S not only the feed gas G but also an inert gas such as argon or nitrogen gas, an active species gas such as oxygen gas, and various other gases used in CCP-CVD. In this case of introducing more than one species of gas, the respective gases may be mixed together in the same pipe and the mixture be passed through the plurality of holes in the film depositing electrode 42 to be supplied into the clearance S; alternatively, the respective gases may be supplied through different pipes and passed through the plurality of holes in the film depositing electrode 42 to be supplied into the clearance S.

The kinds of the feed gas, the inert gas and the active species gas, as well as the amounts in which they are introduced may be chosen and set as appropriate for various considerations including the kind of the film to be formed and the desired film deposition rate.

The partition section 48 demarcates the film depositing electrode 42 within the film depositing compartment 14.

The partition section 48 is typically composed of a pair of partition plates 48a, which are so placed as to hold the film depositing electrode 42 between them.

Each of the partition plates 48a is a member in plate form that extends along the axis of rotation L of the drum 26 (in the longitudinal direction), with its end portion closer to the drum being bent away from the film depositing electrode 42. The partition section 48 demarcates the clearance S, or the plasma generating space, within the film depositing compartment 14.

Note that the radio-frequency power source 44 may be of any known type that is employed in film deposition by plasma-enhanced CVD. The maximum power output and other characteristics of the radio-frequency power source 44 are not particularly limited and may be chosen and set as appropriate for various considerations including the kind of the film to be formed and the desired film deposition rate.

The film depositing electrode 42 is in no way limited to a rectangular plate form and various other electrode configurations may be adopted as long as they are capable of film deposition by capacitively coupled plasma enhanced CVD; to give one example, it may consist of electrode segments that are arranged in the axial direction of the drum 26.

In the embodiment under consideration, the film depositing electrode 42 is of such a configuration that through-holes b are formed in each of the surfaces 52a, 54a and 56a of the film depositing electrodes 52, 54 and 56. However, this is not the sole embodiment of the present invention and end portions 59a, 59b by which the film depositing electrodes 52 and 54, and the film depositing electrodes 54 and 56 are connected to each other, respectively may be spaced apart to form slits of opening, through which the feed gas G may be released.

In the embodiment under consideration, the distribution of the values of the distance d₁, d₂, or d₃ between the surface 52a, 54a or 56a of the film depositing electrode plate 52, 54, or 56 and the surface 26a of the drum 26, namely, the distribution of the values of the distance of the clearance S between the film depositing electrode 42 and the drum 26 lies within 20% over the entire region of the film depositing electrode 42.

The expression reading “lies within 20% over the entire region of the film depositing electrode 42” means within ±10% of the average of the values of the distance as measured in the clearance S. One method to determine the distribution of the values of the distance d₁, d₂, or d₃ (the distance in the clearance S) is as follows: the average of a maximum and a minimum value of the distance is first determined; then, the proportion of the difference between the maximum and minimum values with respect to the average value is determined; and the value of the calculated proportion is used as the distribution of interest.

In the present invention, if the distribution of the values of the distance d₁, d₂, or d₃ (the distance in the clearance S) is held to lie within 20% over the entire region of the film depositing electrode 42, a homogeneous film can be formed in the direction of rotation ω, whereby the quality of the film obtained becomes uniform enough to produce a satisfactory film.

If, on the other hand, the distribution of the values of the distance d₁, d₂, or d₃ exceeds 20% over the entire region of the film depositing electrode 42, a film portion formed in that region of the film depositing electrode 42 which is the closest to the drum 26 differs from another film portion formed in that region which is the farthest from the drum 26, whereupon the formed film taken as a whole is not uniform in quality.

Note here that the expression reading “lie within 20% over the entire region of the film depositing electrode 42” may mean within ±10% of the value at which the distance of the clearance S between the drum 26 (to be more exact, its surface 26a) and the film depositing electrode 42 is set.

Suppose the case where the film depositing electrode is composed of more than one film depositing electrode plate in rectangular form as exemplified by the film depositing electrode 42 according to the embodiment under consideration which consists of the three film depositing electrode plates 52, 54 and 56; the distribution of the values of the distance between the surface 52a, 54a or 56a of the film depositing electrode plate 52, 54, or 56 in the film depositing electrode 42 and the surface 26a of the drum 26, namely, the distribution of the values of the set distance d of the clearance S lies within 20% over the entire region of the film depositing electrode 42 if the following relationship (1) is satisfied.

In the relationship (1), R (mm) is the radius of the drum 26 and d (mm) is the distance between the drum 26 (to be more exact, its surface 26a) and the surface 52a, 54a or 56a of the film depositing electrode plate 52, 54, or 56 in the film depositing electrode 42 (see FIG. 3).

Also suppose the following on the assumption that the film depositing electrode 42 consists of the three film depositing electrode plates 52, 54 and 56: the line by which the end portion 42e of the film depositing electrode plate 52—positioned most upstream in the direction of rotation ω of the drum 26—which is on the upstream side Du in the direction of rotation ω is connected to the center of rotation O of the drum 26 is written as the first line L₁; the line by which the end portion 42e of the film depositing electrode plate 56—positioned most downstream in the direction of rotation ω of the drum 26—which is on the downstream side Dd in the direction of rotation ω is connected to the center of rotation O of the drum 26 is written as the second line L₂; the angle formed between the first line L₁ and the second line L₂ is written as θ. Since a film is deposited on the surface Zf of the substrate Z over the range of angle θ, the range of angle θ is the film deposition zone.

Symbol n in the relationship (1) represents the number of the film depositing electrode plates that are arranged in the direction of rotation ω.

COS(θ/2n)≧(R+0.9d)/(R+1.1d) (1)

If the above relationship (1) is satisfied in the embodiment under consideration, a homogeneous film can be formed in the direction of rotation ω, whereby the quality of the film obtained becomes uniform enough to produce a satisfactory film.

On the other hand, if the relationship (1) is not satisfied, the film formed in that region of the film depositing electrode 42 which is the closest to the drum 26 differs from the film formed in that region of the film depositing electrode 42 which is the farthest from the drum 26, whereupon the formed film taken as a whole is not uniform in quality.

We next describe how the film depositing apparatus 10 according to the embodiment under consideration works.

In the specified path starting from the feed compartment 14 and passing through the film depositing compartment 14 to reach the take-up compartment 16, the elongated substrate Z is transported through the film depositing apparatus 10 from the feed compartment 12 down to the take-up compartment 16 while a film is formed on the substrate Z in the film depositing compartment 14.

In the film depositing apparatus 10, the elongated substrate Z that has been wound around the substrate roll 20 is unwound and transported into the film depositing compartment 14 via the guide roller 21. In the film depositing compartment 14, the substrate Z passes over the guide roller 24, the drum 26 and the guide roller 28 to be transported into the take-up compartment 16. In the take-up compartment 16, the elongated substrate Z passes over the guide roller 31 to be wound up by the take-up roll 30. After passing the elongated substrate Z through this transport path, a specified degree of vacuum is maintained in the interiors of the feed compartment 12, the film depositing compartment 14 and the take-up compartment 16 by means of the evacuating unit 32; then, in the film depositing unit 40, a radio-frequency voltage is applied from the radio-frequency power source 44 to toe film depositing electrode 42 while, at the same time, the feed gas G to form a film is supplied from the feed gas supply section 46 through the pipe 47 and the holder 58 so that it is released through the plurality of through-holes b formed in each of the surfaces 52a, 54a and 56b of the film depositing electrode plates 52, 54 and 56.

When electromagnetic waves are radiated around the film depositing electrode 42, a plasma localized in the neighborhood of the film depositing electrode 42 is generated in the clearance S, whereupon the feed gas is excited and dissociated to yield a reaction product that serves to form a film. This reaction product accumulates to form a specified film on the surface Zf of the substrate Z.

Then, the substrate roll 20 around which the elongated substrate Z has been wound is rotated clockwise incrementally by means of the motor, whereupon the elongated substrate Z is delivered continuously and with the substrate Z being held on the drum 26 in the position where the plasma is being generated, the drum 26 is rotated at a specified speed to ensure that the film depositing unit 40 allows a film to be formed continuously on the surface Zf of the elongated substrate Z. As a result, the substrate Z having the specified film formed on its surface Zf, namely, a functional film, is produced. The function of the functional film produced depends on the properties or the type of the film formed on the substrate Z. The substrate Z having the specified film formed on its surface Zf passes over the guide rollers 28 and 31 so that the functional film, or the elongated substrate Z with the deposited film, is wound up by the take-up roll 30.

Described above is the way in which the substrate Z having the specified film formed on its surface Zf, namely, the functional film can be produced by the film depositing apparatus 10 according to the embodiment under consideration.

When a film is formed on the surface Zf of the elongated substrate Z by the film depositing apparatus 10 in the embodiment under consideration, the distribution of the values of the distance d₁, d₂, or d₃ between the surface 52a, 54a or 56a of the film depositing electrode plate 52, 54 or 56 and the surface 26a of the drum 26 lies within 20% over the entire region of the film depositing electrode 42. As a result, within the working range of the film depositing electrode 42, namely, within the film deposition zone demarcated by the range of angle θ about the center of rotation O of the drum 26, a homogeneous film of a specified thickness can be formed on the surface Zf of the substrate Z.

As a further advantage, adjustment of the distance d₁, d₂, or d₃ between the surface 52a, 54a or 56a of the film depositing electrode plate 52, 54, or 56 and the surface 26a of the drum 26 is easy to perform because it simply involves changing the inclination of the film depositing electrode plate 52, 54, or 56. Since adjustment of the film depositing electrode plate 52, 54, or 56 in the embodiment under consideration merely involves changing their inclination, the device configuration can be simplified. As a result, the apparatus can be manufactured at low cost. In addition, the film depositing electrode plates 52, 54 and 56 are in a rectangular form, so the device configuration is simple and the apparatus can be manufactured easily and at low cost.

Yet another advantage of the film depositing apparatus 10 is that the first temperature adjusting section 27 and the second temperature adjusting section 60 allow the drum 26 and the film depositing electrode 42 to have the same temperature. As a result, even if a temperature elevation occurs due to plasma during film deposition, the drum 26 and the film depositing electrode 42 can be controlled to have the same temperature so that the distribution of the values of the distance d₁, d₂, or d₃ can be suppressed from fluctuating on account of thermal deformation. As a consequence, the distribution of the values of the distance d₁, d₂, or d₃ between the surface 52a, 54a or 56a of the film depositing electrode plate 52, 54 or 56 and the surface 26a of the drum 26 can be held to lie within 20% over the entire region of the film depositing electrode 42.

In the embodiment under consideration, the film to be deposited is not particularly limited and as long as CCP-CVD is applicable, films having the required functions that depend on the functional films to be produced can appropriately be formed. The thickness of the film to be deposited also is not particularly limited and the required thickness may be determined as appropriate for the performance required by the functional film to be produced.

It should also be noted that the film to be deposited is not limited to a single-layer structure but may be composed of more than one layer. If a multi-layer film is to be formed, the individual layers may be the same or different from each other.

In the embodiment under consideration, if a gas barrier film (water vapor barrier film) is to be produced as the functional film, the film to be deposited on the substrate is an inorganic film such as a silicon nitride film, an aluminum oxide film, or a silicon oxide film.

If protective films for a variety of devices or apparatuses including display devices such as organic EL displays and liquid-crystal displays are to be produced as the functional film, the film to be deposited on the substrate is an inorganic film such as a silicon oxide film.

Further in addition, if the functional film produced is any of an anti-light reflective film, a light reflective film, and various other optical films for use in filters, the film to be deposited on the substrate is a film having the desired optical characteristics or a film comprising materials that exhibit the desired optical characteristics.

The functional film thus produced by the film depositing apparatus 10 according to the embodiment under consideration has a film of good quality formed on the substrate, so if it is a gas barrier film, it has good enough gas barrier property.

While the film depositing apparatus of the present invention has been described above in detail, the present invention is by no means limited to the foregoing embodiment and it should be understood that various improvements and modifications are possible without departing from the scope and spirit of the present invention.

### EXAMPLES

On the following pages, concrete examples of the present invention are described in order to make a more detailed explanation of the present invention. It should, however, be noted that the following examples are for illustrative purposes only and are by no means intended to limit the scope of the present invention.

### Examples 1-3 and Comparative Example 1

The following experiments were conducted to verify the criticality of ensuring that the distribution of the values of the distance of the clearance S between the film depositing electrode 42 and the drum 26 would lie within 20% over the entire region of the film depositing electrode 42.

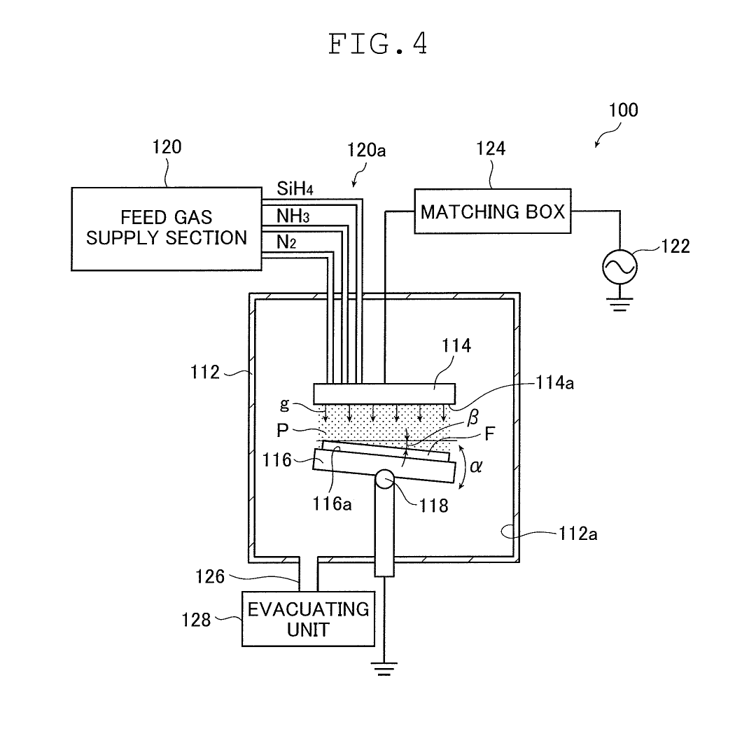

Using a capacitively coupled plasma enhanced CVD apparatus indicated by 100 in FIG. 4, silicon nitride films were formed on polyethylene naphthalate substrates (PEN film; product of Teijin DuPont Films Japan Limited; trade name, Teonex® Q65FA) with the electrode-to-electrode distance and the distribution of interest being varied as shown in Table 1 below. The thus formed silicon nitride films were evaluated for WVTR (water vapor transmission rate). The results are also shown in Table 1.

The conditions for film deposition were as follows: the flow rate of SiH₄ gas (silane gas) was 50 sccm; the flow rate of NH₃ gas (ammonia gas) was 100 sccm; the flow rate of N₂ gas (nitrogen gas) was 350 sccm; and the applied RF power was 1000 W. The polyethylene naphthalate substrates are hereinafter referred to simply as film F.

Each of the distributions shown in Table 1 was determined by the following method: the average of a maximum and a minimum value was first determined; then, the proportion of the difference between the maximum and minimum values of the distance with respect to the average value was determined; and the value of the calculated proportion was used as the distribution of interest.

For WVTR (water vapor transmission rate) measurement, a water vapor transmission rate tester PERMATRAN-W3/33 MG module of MOCON, Inc. was used.

The capacitively coupled plasma enhanced CVD apparatus 100 used to form silicon nitride films had a shower head electrode 114 and a lower electrode 116 spaced apart in a face-to-face relationship in the interior 112a of a vacuum chamber 112.

The shower head electrode 114 served both as an electrode for discharging plasma P and as a device to ensure that a mixed gas g consisting of feed gases (silane and ammonia gases) for forming a silicon nitride film and a discharge gas (nitrogen gas) would be so supplied from the surface 114a as to cover the top surface of the film F uniformly. The shower head electrode 114 had a number of through-holes (not shown) formed at equal spacings in its surface 114a.

The shower head electrode 114 was supplied with the feed gases (silane and ammonia gases) and the discharge gas (nitrogen gas) individually at specified flow rates through associated supply pipes 120a as the respective gases were coming from a feed gas supply section 120. Through the plurality of through-holes in the surface 114a of the shower head electrode 114, the mixed gas g consisting of silane/ammonia gases and nitrogen gas was supplied into the clearance between the shower head electrode 114 and the lower electrode 116.

Note that the feed gas supply section 120 had the same structure as the feed gas supply section 46 of the film depositing apparatus 10 shown in FIG. 1.

The shower head electrode 114 was also connected to a radio-frequency power source 122 via a matching box 124 for establishing impedance matching. The radio-frequency power source 122 was capable of varying the radio-frequency power (RF power) that was to be applied to the shower head electrode 114.

By the radio-frequency power (RF power) as applied in the plasma-enhanced CVD apparatus 100 shown in FIG. 4 was meant the radio-frequency power that the radio-frequency power source 122 provided in the apparatus would apply to the shower head electrode 114 during film deposition. A value of the radio-frequency power can be measured by a wattmeter with which the radio-frequency power source may be typically equipped.

The lower electrode 116 was for generating plasma P in conjunction with the shower head electrode 114; on its surface 116a was provided a holder (not shown) on which the film F was to be set. Note that the lower electrode 116 was electrically connected to the ground.

The vacuum chamber 112 was connected to an evacuating unit 128 via an evacuation pipe 126. This evacuating unit 128 would create a specified degree of vacuum in the interior 112a of the chamber 112.

The lower electrode 116 was equipped with a rocking mechanism 118 by which its surface 116a would be rocked in directions indicated by α. This rocking mechanism 118 was capable of inclining the surface 116a of the lower electrode 116 through a specified angle β.

By means of this rocking mechanism 118, the film F could be inclined such that the electrode-to-electrode distance between the film F and the shower head electrode 114 would not be constant but have a distribution.

In the experiments under consideration, the silicon nitride films were formed in the following manner.

First, the film F was set in the holder provided on the surface 116a of the lower electrode 116 in the interior 112a of the vacuum chamber 112 shown in FIG. 4. Then, the rocking mechanism 118 was so operated as to provide the electrode-to-electrode distances indicated in Table 1. Thereafter, the vacuum chamber 112 was closed.

Subsequently, the interior of the vacuum chamber 112 was evacuated by means of the evacuating unit 128 and at the point in time when the internal pressure dropped to 7×10⁻⁴ Pa, silane, ammonia and nitrogen gases were introduced at respective flow rates of 50 sccm, 100 sccm, and 350 sccm.

Then, a RF power of 1000 W was applied to the shower head electrode 114 as it was supplied from the radio-frequency power source 122, whereby a silicon nitride film began to form on the surface of the film F.

The silicon nitride film was deposited for a preset period of time and after the passage of that preset time, the step of film deposition was completed and the film F having the silicon nitride film formed on it was recovered from the vacuum chamber 112.

TABLE 1

| | | | | | Com- |
|---|---|---|---|---|---|
| | | | | | parative |
| | | Example 1 | Example 2 | Example 3 | Example 1 |
| Electrode- | Minimum | 28.6 | 27.6 | 26.9 | 26.3 |
| to- | value | | | | |
| electrode | (mm) | | | | |
| distance | Maximum | 31.5 | 32.2 | 32.9 | 33.7 |
| | value | | | | |
| | (mm) | | | | |
| | Distribution | 10 | 15 | 20 | 25 |
| | (%) | | | | |

| | | | | |
|---|---|---|---|---|
| WVTR (g/m²/day) | 0.04 | 0.05 | 0.08 | 0.15 |

As Table 1 above shows, WVTR values of not more than 0.1 were obtained in Examples 1 to 3 wherein the distribution of the electrode-to-electrode distance was held to lie within 20%.

On the other hand, the WVTR value in Comparative Example 1 was as great as 0.15. Most probably, the barrier property dropped in Comparative Example 1 because the quality of the film in either the area of the maximum electrode-to-electrode distance or the area of the minimum electrode-to-electrode distance or both areas was different from the quality of the film in the other areas.

Thus, if the distribution of the electrode-to-electrode distance lies within 20%, the WVTR values are not more than 0.1 and satisfactory barrier property is obtained.

### Example 4 and Comparative Example 2

The following experiments were conducted to verify the criticality of satisfying the relationship (1) in the roll-to-roll type film depositing apparatus 10 shown in FIG. 1.

By operating the film depositing apparatus 10 under different conditions (see below) in Example 4 and Comparative Example 2, silicon nitride films were formed on rolls of substrate. Thereafter, each of the substrates having the silicon nitride film formed thereon was cut to a specified size and each of the silicon nitride films formed was evaluated for WVTR (water vapor transmission rate).

As in Examples 1 to 3 and Comparative Example 1, the substrate was a polyethylene naphthalate film (PEN film; product of Teijin DuPont Films Japan Limited; trade name, Teonex® Q65FA).

To form the silicon nitride films in Example 4 and Comparative Example 2, SiH₄ gas (silane gas), NH₃ (ammonia gas) and N₂ (nitrogen gas) were used.

For WVTR (water vapor transmission rate) measurement, a water vapor transmission rate tester PERMATRAN-W3/33 MG module of MOCON, Inc. was used.

In Example 4, the film depositing apparatus 10 was operated under the following conditions: angle θ was 90°; the radius R of the drum 26 was 500 mm; the set distance d between the drum 26 and the film depositing electrode 42 was 20 mm; the number n of film depositing electrode plates arranged in the direction of rotation ω of the drum 26 was 7. The relationship (1) expressed by COS(θ/2n)≧(R+0.9d)/(R+1.1d) was satisfied in Example 4 and the distribution of the set distance d of the clearance S lied within 20% over the entire region of the film depositing electrode 42.

In Comparative Example 2, the film depositing apparatus 10 was operated under the following conditions: angle θ was 90°; the radius R of the drum 26 was 500 mm; the set distance d between the drum 26 and the film depositing electrode 42 was 20 mm; the number n of film depositing electrode plates arranged in the direction of rotation ω of the drum 26 was 5. The relationship (1) expressed by COS(θ/2n)≧(R+0.9d)/(R+1.1d) was not satisfied in Comparative Example 2 and the distribution of the set distance d of the clearance S exceeded 20%.

In Example 4, the value of WVTR (g/m²/day) was 0.06 but in Comparative Example 2, it was 0.13. Thus, in Example 4 that satisfied the relationship (1), the value of WVTR was small enough not to exceed 0.1 and satisfactory barrier property was obtained.

What is claimed is:

1. A film depositing apparatus comprising:
a transport means that transports an elongated substrate in a specified transport path;
a chamber;
an evacuating unit that creates a specified degree of vacuum within the chamber;
a rotatable drum that is provided within the chamber, that has an axis of rotation in a direction perpendicular to a direction in which the substrate is transported, and around which the substrate transported by the transport means is wrapped in a specified surface region; and
a film depositing unit comprising a film depositing electrode spaced apart from and in a face-to-face relationship with the drum, a radio-frequency power source section for applying a radio-frequency voltage to the film depositing electrode, and a feed gas supply section from which a feed gas for forming a film is supplied into a space between the drum and the film depositing electrode,
wherein a distribution of values of a distance between the film depositing electrode and the drum lies within 20% over an entire region of the film depositing electrode.

2. The film depositing apparatus according to claim 1, wherein each of the drum and the film depositing electrode is equipped with a temperature adjusting mechanism.

3. The film depositing apparatus according to claim 1, wherein the film depositing electrode comprises film depositing electrode plates in rectangular form that are arranged in such a way that their longitudinal direction aligns with the axis of rotation of the drum, the film depositing electrode plates contacting each other on a side closer to the drum so as to establish electrical conduction and being independently adjustable for their distance from the drum.

4. The film depositing apparatus according to claim 3, which satisfies COS(θ/2n)≧(R+0.9d)/(R+1.1d) wherein R is a radius of the drum; d is the distance between the drum and each of the film depositing electrode plates, θ is an angle formed between a first line and a second line, the first line being a line by which a first end portion of one of the film depositing electrode plates positioned most upstream in a direction of rotation of the drum, the first end portion being on an upstream side in the direction of rotation of the drum, is connected to a center of rotation of the drum, and the second line being a line by which a second end portion of one of the film depositing electrode plates positioned most downstream in the direction of rotation of the drum, the second end portion being on a downstream side in the direction of rotation of the drum, is connected to the center of rotation of the drum; and n is a number of the film depositing electrode plates that are arranged.

5. The film depositing apparatus according to claim 1, wherein the film depositing electrode is a shower head electrode.

6. The film depositing apparatus according to claim 3, wherein each of the film depositing electrode plates has through-holes formed in it, and the feed gas is supplied from the feed gas supply section through the through-holes into the space between the drum and the film depositing electrode.
